(19) United States
(12) Patent Application Publication
(10) Pub. No.: US 2014/0048925 A1
(43) Pub. Date: Feb. 20, 2014

(54) INTEGRATED CIRCUIT

(71) Applicant: MENG-CHE YU, Tu-Cheng (TW)

(72) Inventor: MENG-CHE YU, Tu-Cheng (TW)

(73) Assignee: HON HAI PRECISION INDUSTRY CO., LTD., Tu-Cheng (TW)

(21) Appl. No.: 13/598,651

(22) Filed: Aug. 30, 2012

(30) Foreign Application Priority Data
Aug. 14, 2012 (TW) 101129438

(51) Int. Cl. H01L 23/49

(52) U.S. Cl. 257/735; 257/E23.024

(57) ABSTRACT

An integrated circuit includes a main body, a number of connection tabs molded on the main body, and a number of pins respectively connected to the connection tabs. The connection tabs and the pins are made of metal. The connection tabs are electrically connected to a logic circuit in the main body.

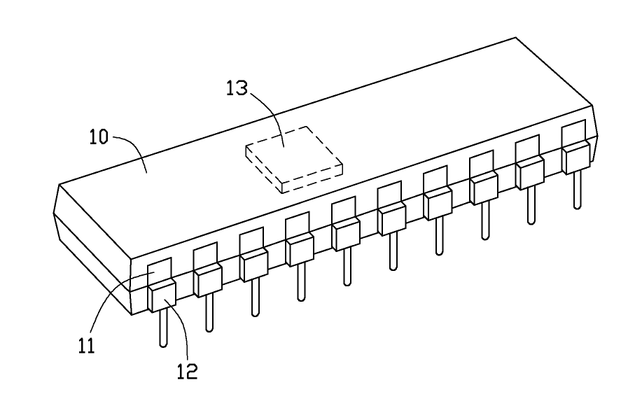

### BACKGROUND

1. Technical Field

The present disclosure relates to an integrated circuit.

2. Description of Related Art

For a conventional integrated circuit, there is a plurality of pins molded to the integrated circuit. If any one of the pins is damaged, the integrated circuit becomes unusable. Therefore, a new type of integrated circuit is needed.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments. Moreover, in the drawing, the view is schematic, and like reference numerals designate corresponding parts throughout the view.

The FIGURE is an isometric view of an exemplary embodiment of an integrated circuit.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

The FIGURE shows an exemplary embodiment of an integrated circuit including a main body 10, a plurality of connection tabs 11 molded on opposite sides of the main body 10, and a plurality of pins 12. The connection tabs 11 and the pins 12 are made of metal. The connection tabs 11 are electrically connected to a logic circuit 13 in the main body 10. The pins 12 are respectively welded on the connection tabs 11.

The contacting area between the connection tabs 11 and the pins 12 is large, so that the pins 12 are not easily broken. Even if one of the pins 12 is broken, the solder of the pin 12 can be melted, and a new pin 12 welded on the corresponding connection tab 11 in its stead.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

1. An integrated circuit, comprising:
a main body;
a plurality of connection tabs molded on the main body and exposed outside; and
a plurality of pins respectively connected to the connection tabs;
wherein the connection tabs and the pins are made of metal, the connection tabs are electrically connected to a logic circuit in the main body.

2. The integrated circuit of claim 1, wherein the pins are respectively welded on the connection tabs.

3. The integrated circuit of claim 1, wherein the connection tabs are molded on opposite sides of the main body.
